(19) United States
(12) Patent Application Publication
(10) Pub. No.: US 2003/0146786 A1
(43) Pub. Date: Aug. 7, 2003

(54) ADC having chopper offset cancellation

(76) Inventors: Kush Gulati, Waltham, MA (US); Hae-Seung Lee, Bedford, MA (US)

Correspondence Address: DALY, CROWLEY & MOFFORD, LLP, SUITE 101, 275 TURNPIKE STREET, CANTON, MA, 02021-2310, US

(21) Appl. No.: 10/352,467

(22) Filed: Jan. 28, 2003

Related U.S. Application Data
(60) Provisional application No. 60/354,317, filed on Feb. 4, 2002.

(51) Int. Cl. H03F 1/02

(52) U.S. Cl. 330/9

(57) ABSTRACT

A circuit includes an amplifier circuit and a chopper offset cancellation circuit for chopping a switched capacitor circuit. In one embodiment, an Analog-to-Digital Converter (ADC) circuit includes chopper offset cancellation.

### CROSS-REFERENCE TO RELATED APPLICATIONS

The present application claims the benefit of U.S. Provisional Patent Application No. 60/354,317, filed on Feb. 4, 2002, which is incorporated herein by reference.

### STATEMENTS REGARDING FEDERALLY SPONSORED RESEARCH

The Government may have certain rights in the invention pursuant to DARPA Contract No. DAAL-01-95-K-3526.

### FIELD OF THE INVENTION

This invention relates generally to integrated circuits and, more particularly, to circuits including time-switched capacitors having noise and/or offset cancellation.

### BACKGROUND OF INVENTION

As is known in the art, switched-capacitor integrators and gain-stages employing operational amplifiers are used in a variety of applications, such as in the analog loop filter of a delta-sigma analog-to-digital converter (ADC) and in a pipeline ADC. However, the operational amplifiers in integrators and gain-stages produce flicker (1/f) noise and low frequency interference, which degrades the performance of the converter. Flicker noise is discussed, for example, in R. Gregorian, “Analog MOS Integrated Circuits for Signal Processing,” at pages 500-505, which is incorporated herein by reference. Specific to a delta-sigma converter, flicker noise from the first integrator in the loop filter can significantly reduce the signal-to-noise ratio (SNR) of the digitized signal.

One known method to attenuate the flicker noise and low frequency interference in switched-capacitor filters is to chopper-stabilize the amplifier in the integrator. This technique is described in, for example, Hsieh, et al. “A Low-Noise Chopper-Stabilized Differential Switched-Capacitor Filtering Technique,” IEEE Journal of Solid-State Circuits, Vol. SC-16, No. 6, pp. 708-715, which is incorporated herein by reference. This technique involves swapping the inputs and outputs of the operational amplifiers each clock cycle. This process does not disturb the normal functioning of the converter, however, it is tantamount to multiplying the low frequency noise by a square wave with a frequency that is one-half the sampling frequency Fs. This is equivalent to modulating the noise to a frequency Fs/2 that is relatively far away from the frequency band occupied by the input. Subsequent digital filtering by a decimation filter, typically employed by delta-sigma converters, removes the modulated 1/f noise.

The implementation of such a chopping mechanism has traditionally been done in ways (see e.g., Hseih et. al.) that degrade the performance of the integrator or the gain-stage, where the opamp is employed. For example, typical prior art implementations add white noise, degrade the speed of the integrator of the gain-stage, or both.

It would, therefore, be desirable to overcome the aforesaid and other disadvantages of known chopper offset circuit configurations.

### SUMMARY OF THE INVENTION

The present invention provides a chopping mechanism for a switched-capacitor circuit by chopping a charge packet delivered to an integrating circuit. With this arrangement, opamp offset is reduced or canceled while offering an enhanced signal-to-noise ratio (SNR) and overall circuit performance in comparison with conventional chopper offset cancellation schemes. While the invention is primarily shown and described in conjunction with Analog-to-Digital Converter (ADC) circuits, and more particularly, delta-sigma type ADCs, it is understood that the invention is generally applicable to switched-capacitor circuits where it is desirable to minimize circuit offset and low frequency noise.

In one aspect of the invention, a circuit having chopper offset cancellation includes a differential amplifier circuit and a differential capacitive element coupled across the amplifier circuit in an integrating feedback configuration. The circuit further includes an offset cancellation mechanism having input cross-coupled switches coupled between the differential capacitive element and the amplifier circuit inputs. Output cross-coupled switches are coupled between the differential capacitive element and the amplifier circuit outputs. The input and output cross-coupled switches enable swapping of the amplifier circuit inputs and outputs to cancel chopper offset.

### BRIEF DESCRIPTION OF THE DRAWINGS

The invention will be more fully understood from the following detailed description taken in conjunction with the accompanying drawings, in which:

FIG. 1 a is a block diagram of a delta-sigma converter having chopper offset cancellation in accordance with the present invention;

FIG. 1b is a block diagram showing further details of the converter of FIG. 1a shown as a 4th order delta-sigma modulator;

FIG. 2 is a schematic diagram of a prior art integrator circuit;

FIG. 3 is a timing diagram showing signals used by the circuit of FIG. 2;

FIG. 4 is a schematic diagram of a prior art integrator circuit having cross-coupled switches for offset cancellation;

FIG. 4A is a schematic diagram showing the prior art circuit of FIG. 4 in a first state;

FIG. 5 is a timing diagram showing signals used by the circuit of FIG. 4;

FIG. 6 is a schematic diagram of a circuit including an integrator circuit having chopper offset cancellation in accordance with the present invention;

FIG. 6A is a timing diagram showing signals used by the circuit of FIG. 6;

FIG. 6B is a schematic diagram showing the circuit of FIG. 6 in a first state;

FIG. 7 is a graphical depiction of the spectrum of a digitized signal with opamp chopping disabled; and

FIG. 8 is a graphical depiction of the spectrum of a digitized signal with opamp chopping in accordance with the present invention.

### DETAILED DESCRIPTION OF THE INVENTION

The present invention provides a circuit, such as an Analog-to-Digital Converter (ADC) circuit, having enhanced chopper offset cancellation performance. While the invention is primarily shown and described in conjunction with integrator circuits and ADCs, and in particular, a delta-sigma modulator type ADC, it is understood that the invention is applicable to ADCs and circuits in general in which chopper offset cancellation is desirable.

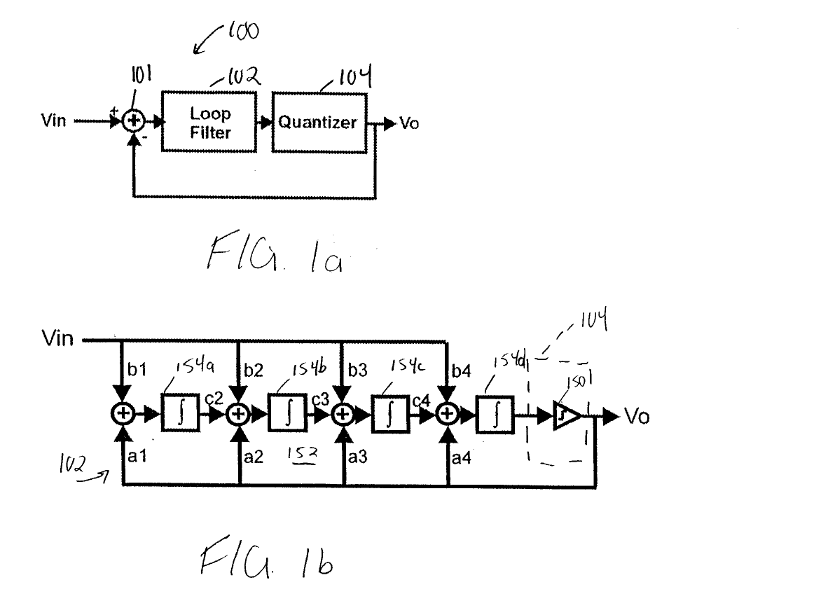

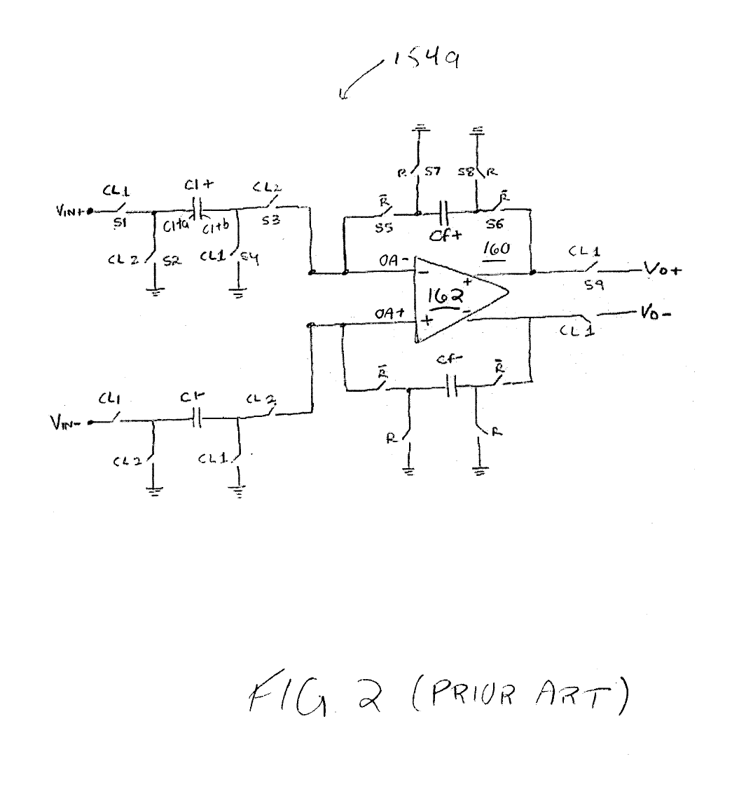

FIG. 1a shows an exemplary ADC, shown as a delta-sigma modulator 100, having chopper offset cancellation in accordance with the present invention. The delta-sigma modulator 100 includes a summer 101, a loop filter 102, which can be provided as a low-pass filter, and a quantizer 104. In one embodiment, the quantizer 104 corresponds to a relatively simple comparator that compares the output of the loop filter 102 to zero and generates a digital one or a zero based on the comparison. An input signal Vin to the modulator 100 is an analog quantity while the modulator output signal Vo is a 1-bit digital output that may change each time the comparator is strobed, i.e., every clock cycle. The gain of the loop filter 102 ensures that the average value of the digital output over time tracks the relatively slow moving analog input. As described in detail below, the modulator 100 includes chopper offset cancellation by chopping a signal presented to an input of an amplifying circuit, such as an operational amplifier.

FIG. 1b shows an illustrative implementation of the modulator 100 of FIG. 1a in which like elements have like reference numbers. Portions of the modulator are described in S. Norsworthy et. al., “Delta-Sigma Data Converters-Theory, Design and Simulation,” IEEE Press, New Jersey, 1997, on pages 178-180, which is incorporated herein by reference. The quantizer 104 is provided as a comparator 150. The loop (low pass) filter 102 is implemented in a filtering structure 152 shown as a 4th order delta-sigma modulator. The filtering structure 152 includes a series of integrator modules 154a-d each providing an integrating or low-pass filtering operation. The right-most integrator module 154d provides a signal to the comparator 150. The coefficients of the filter are realized by the gain in each of the branches of the filter as shown. As shown, coefficients b1, b2, b3 and b4 are the feedforward coefficients while coefficients a1, a2, a3 and a4 comprise the feedback coefficients. As known to one of ordinary skill in the art, these coefficients define the location of the poles and zeros of the filter.

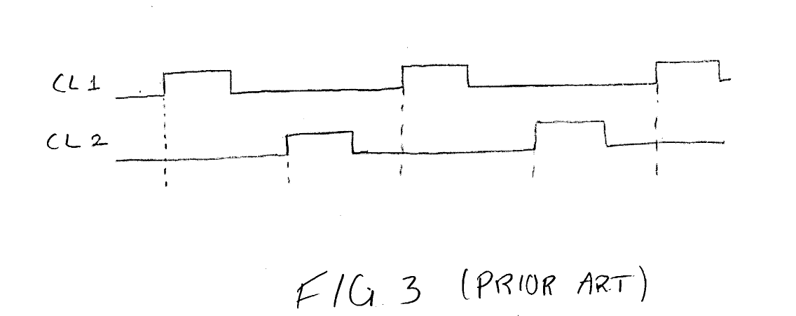

FIG. 2 shows an exemplary prior art implementation of one of the integrator modules 154 of FIG. 1b in which like reference elements indicate like elements, shown without offset cancellation to facilitate an understanding of the present invention, which is described in detail below. In one embodiment, the integrator module, e.g., the left-most integrator module 154a, includes a switched-capacitor circuit 160, which will be described in conjunction with the clock signals of FIG. 3, along with an operational amplifier 162. It is understood that the integrator module 154a is shown in a differential configuration with only one input shown. It is understood that to implement the first delta-sigma block, two inputs representing each of the two paths ‘b1’ and ‘a1’ (see FIG. 1b) are required. For ease of describing the circuit, only switches in the upper half (+) of the differential circuit are labeled.

FIG. 3 shows an exemplary timing diagram for signals CL1 and CL2 that control the various switches shown in FIG. 2. A reset signal R (not shown), and its complement R-bar represent a reset signal that is used to drain the charge on a filter capacitor Cf. It is understood that the filter capacitor Cf includes differential capacitors Cf+ and Cf−. During this time (reset signal inactive, i.e., R=1) switches S5 and S6 are switched off and the filter capacitor Cf is connected across ground terminals through switches S7 and S8. One of ordinary skill in the art will appreciate that the reset operation does not occur during normal operation of the modulator. It is understood that reset may be necessary each time the modulator becomes unstable.

For normal operation, it is assumed that R=0, in which case the filter capacitor Cf is connected across the opamp 162 through switches S5 and S6. While the first clock signal CL1 is a logical one, a first capacitor C1 (differential capacitors C1+ and C1−) is connected between the input terminals Vin+, Vin− and ground. By the end of this clock phase, the first capacitor C1 has charge corresponding to the input voltage signal Vin. As the second clock signal CL2 pulses high, the left plate C1+a of the first capacitor C1 is connected to ground through switch S2 while the right plate C1+b is connected to the input terminal OA− of the opamp 162. Because, differentially, the input terminals OA−, OA+ of the opamp 162 are virtually shorted to each other, the charge from the first capacitor C1 flows into the filter capacitor Cf. This charge dump on the filter capacitor Cf manifests itself as a change in voltage at the output Vo of the opamp 162. As this process repeats, more charge corresponding to the input is additively dumped onto the filter capacitor Cf. This addition of charge on the filter capacitor Cf corresponds to an integration process, as is well known to one of ordinary skill in the art.

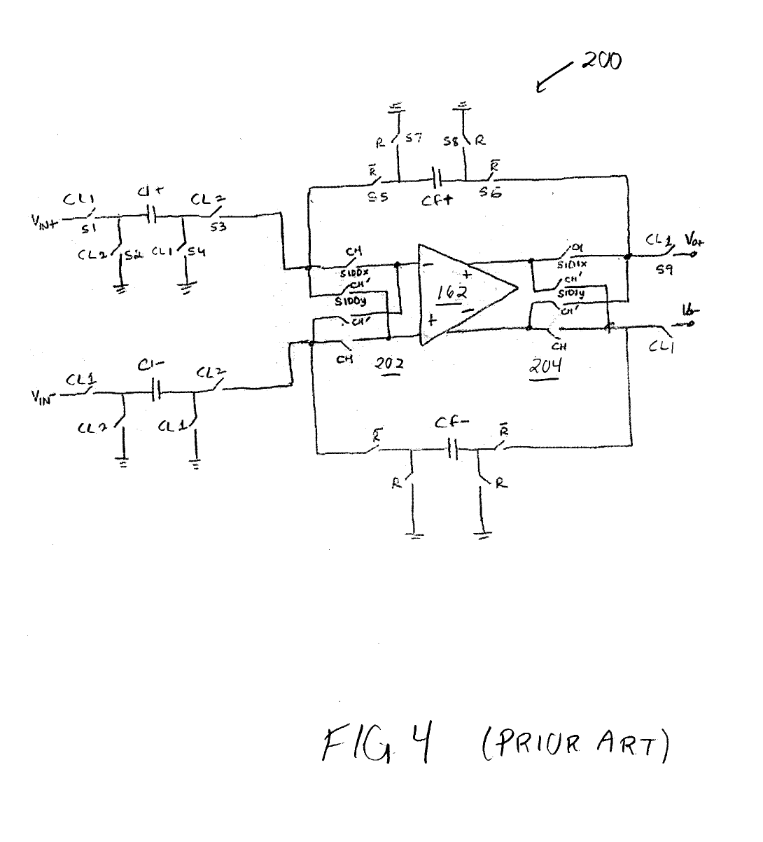

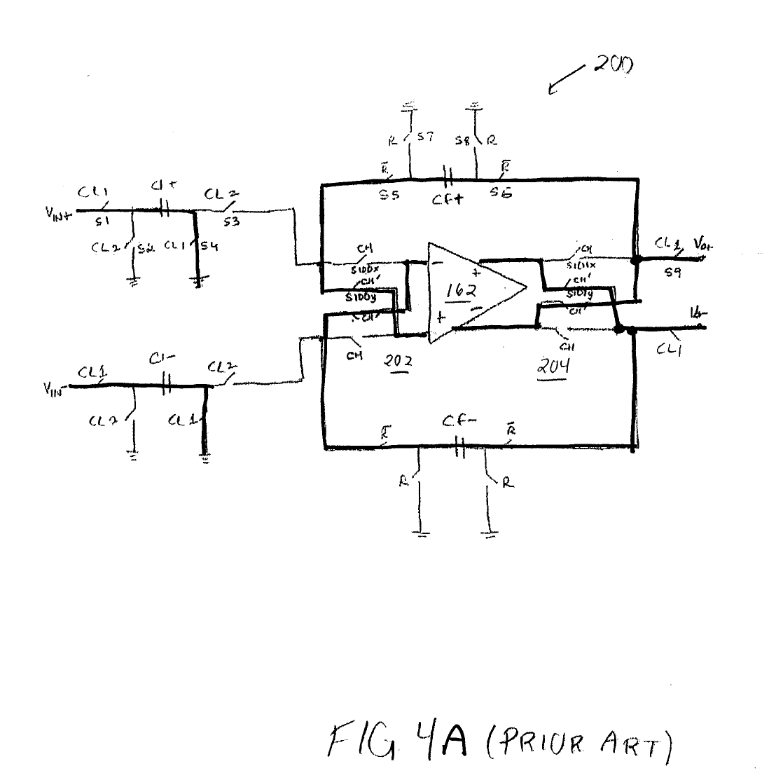

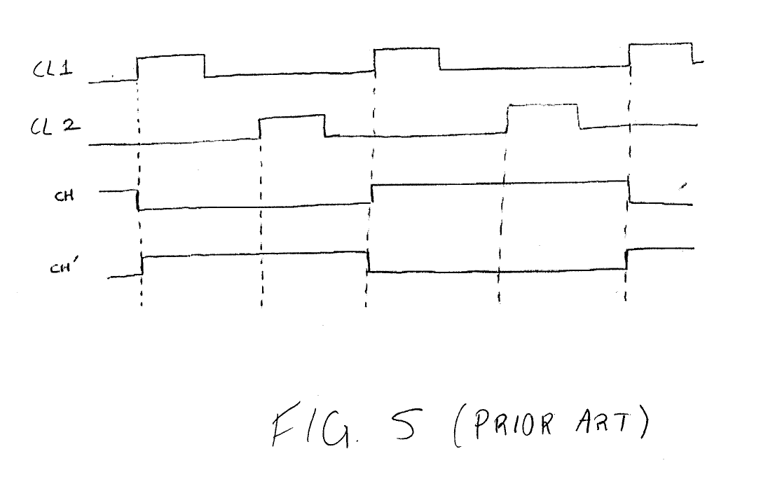

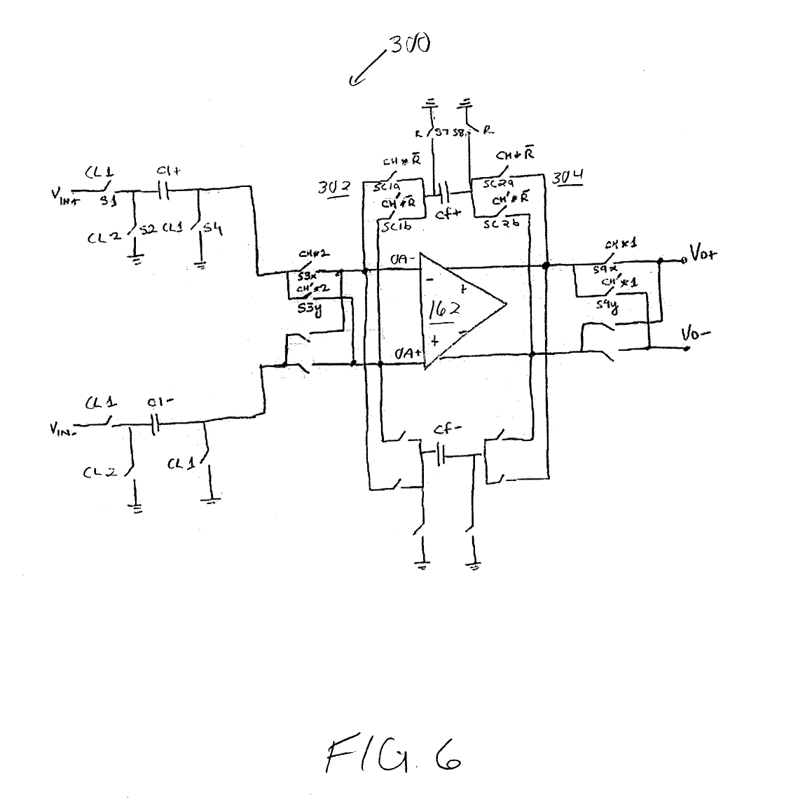

FIG. 4 shows an exemplary prior art chopping implementation 200 that is controlled by the signals shown in the timing diagram of FIG. 5. As described above, operational amplifiers can contribute low frequency noise that can swamp out the low frequency input. FIG. 4 shows a conventional circuit that is employed to push this noise out to a higher frequency away from the input frequency band. In addition to the circuit features shown in FIG. 2, in which like elements have like reference numbers, the circuit shown in FIG. 4 includes an opamp input switching network 202 and an opamp output switching network 204. The signals shown in FIG. 5 include, in addition to the first and second clock signals CL1, CL2 shown in FIG. 3, chopping signals CH, CH′ for controlling the input and output switching networks 202, 204. The chopping signals CH, CH′ provide chopping clocks that run, in one embodiment, at half the frequency of the first and second clocks CL1, CL2.

To minimize the effects of offset and 1/f noise on the performance of an analog-to-digital converter or filter, the opamp 162 is chopped at half the sampling frequency Fs of the circuit. As shown in FIG. 4A, for example, cross-coupled switches S100x, S100y are employed in series with the opamp 162 input and cross-coupled switches S101x, S101y are coupled in series with the amplifier output to implement the chopping operation. Note that these switches S100x, S100y, S101x, S101y are within the integration loop.

The cross-coupled switch pairs S100x, S100y and S101x, S101y are controlled by the chopping signals CH, CH′. The switches S100x, S100y, S101x, S101y swap the inputs and outputs of the opamp 162 each clock cycle and effectively chop the opamp at half the sampling frequency fs/2 independently from the rest of the switched-capacitor circuit.

However, switches S100x and S101x (and S100y, S101y) have a non-zero resistance and thus introduce higher order poles to the closed loop opamp system leading to greater ringing in the settling response of the integrator. This can decrease the overall speed of the converter. Alternatively, these switches could be sufficiently large so as to reduce the impact of the higher order poles on the order of the system. However, this adds additional parasitic capacitance thus reducing the unity-gain frequency of the system. To compensate, the opamps can be made larger, at the cost of higher power consumption. Additionally, the switches in series with the opamp input will contribute thermal noise that will get boosted up by the noise gain of the closed loop system, just like thermal noise from the opamp, and thus reduce the overall signal-to-noise ratio of the converter.

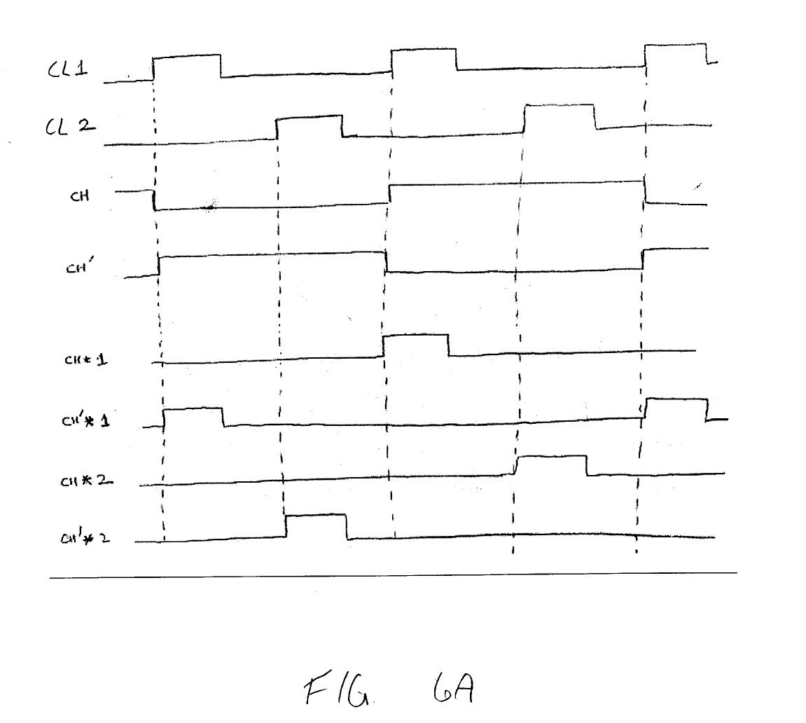

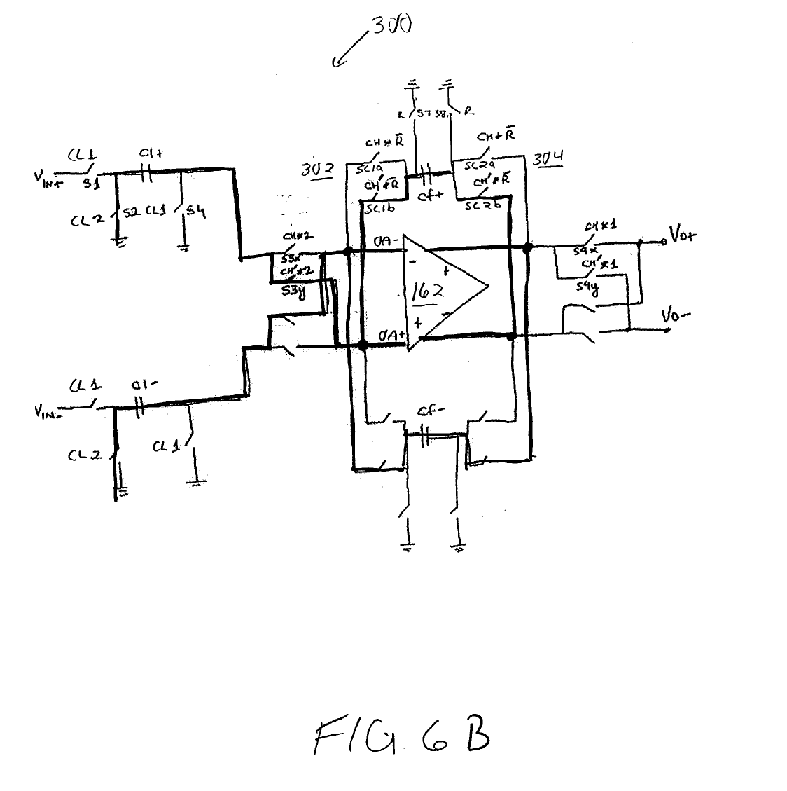

FIG. 6 shows a circuit 300 having opamp chopping in accordance with the present invention in which like reference numbers of FIG. 4 indicate like elements. The circuit includes an input chopping circuit 302 and an output chopping circuit 304. Instead of chopping the opamp 162, as described above, the charge packet that is delivered to the opamp 162 and filter capacitor Cf is chopped between the positive OA+ and negative inputs OA− of the opamp. In other words, the switched-capacitor circuit around the opamp is chopped instead of the opamp since cross-coupled switches are external to the integrator feedback loop, as shown and described below.

FIG. 6A shows a timing diagram having a first chop phase signal CH*1 derived from a logical AND of the chopping signal CH and the first clock signal CL1 and a first inverse chop phase signal CH′*1 is derived from a logical AND of the first clock signal CL1 and the inverse of the chopping signal CH. The second chop phase signal CH*2 and second inverse chop phase signal CH′*2 are similarly derived. These signals CH*1, CH′*1, CH*2, CH′*2 are in addition to the signals shown and described in FIG. 5.

Referring now to FIG. 6 in conjunction with FIG. 6A, the input chopping circuit 302 includes a first switch pair SC1a, SC1b coupled between the respective opamp inputs OA−, OA+ and the filter capacitor Cf. The output chopping circuit 304 includes a second switch pair SC2a, SC2b coupled between the opamp outputs Vo+, Vo− and the integrating capacitor Cf. It is understood that for ease of description only a part of the differential circuit is specifically described and labeled. Absent an active reset signal, respective first ones SC1a, SC2a of the first and second switch pairs are controlled by chop clock signal CH and second ones SC1b, SC2b of the first and second switch pairs are controlled by inverse chop clock signal CH′. The first and second switch pairs enable swapping of the inputs and outputs of the opamp 162.

As shown in FIG. 6B, it can be seen that, in comparison with the prior art arrangement shown in FIG. 4A for example, switches within the feedback loop required for the chopping operation in the prior art have been eliminated. In operation, during the clock period when the inverse chop clock CH′ is HIGH, the stored charge on the input capacitor C1+ from the (+) input signal Vin+ is fed to the positive terminal OA+ of the opamp, while in the next clock period the charge from the input signal Vin+ is delivered to the negative terminal OA− of the opamp 162. In order to maintain the same transfer function, differential portions of the integrating capacitor Cf+, Cf− also are interchanged every other clock period, while the next stage also samples the opamp output signals Vo+, Vo− alternately every clock period. In other words, the charge packets are chopped around the opamp 162.

This operation provides a similar effect as conventional opamp chopping with the cross coupled switches located external to the feedback loop for faster settling time. And while these parallel switches still contribute some parasitic capacitance, the total parasitic capacitance at the opamp inputs can be shown to be about 9/10 ths of its original value, for example. So the total parasitic capacitance due to junction capacitance at the opamp inputs remains roughly similar. The switches next to integrating capacitors Cf+ and Cf− enable resetting of the system in case of modulator instability in both cases.

Removing the switch resistance in series with the opamp inputs and outputs leads to faster settling time and/or lower power compared to the conventional chopping mechanism. This arrangement provides offset chopping in a delta-sigma converter without the performance drop experienced with conventional chopping schemes. Additionally, the noise level of the circuit is also lower compared to conventional approaches because there is no additional switch required for chopping in series with the opamp input within the loop.

The inventive chopping technique was implemented in silicon as part of a fourth order delta-sigma converter, such as the one shown in FIG. 1b. Only the opamp in the first integrator was chopped using the inventive chopping circuit. In general, it is not necessary to chop the opamps in the following stages (integrators) because the 1/f noise and offset of successive integrators is highly attenuated by the high low frequency gain of the first stage when these are referred back to the input. The sampling frequency Fs employed for this measurement is 10 MHz and the input tone applied at the inputs of the converter is 6.25 KHz. The signal-to-noise ratio of the digitized signal is 94 dB.

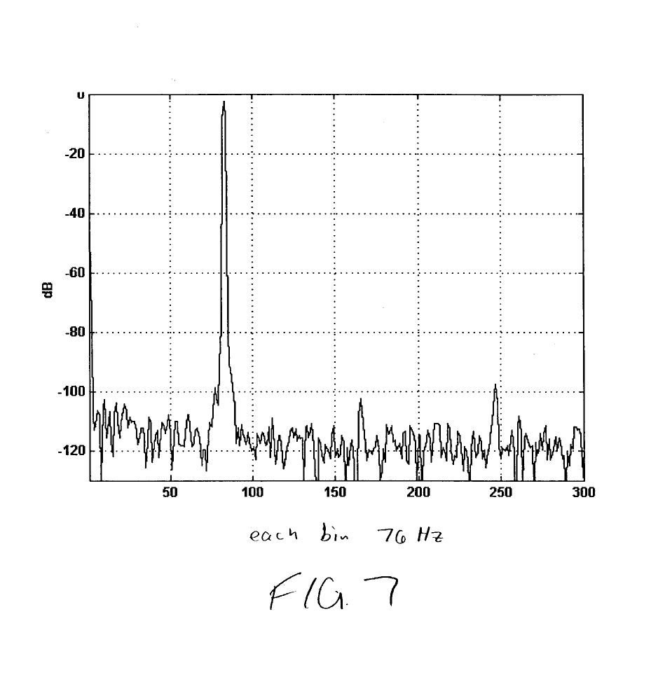

The first block opamp is chopped at fs/2 frequency in order to modulate the 1/f noise to fs/2 frequency. The spectrums of the digitized signal obtained at the output of the delta-sigma converter were compared to monitor the effect of chopping. FIG. 7 shows the spectrum of digitized output where the Y-axis represents magnitude in dB while the X-axis represents bins (or bands, where each bin represents 76 Hz). The spike seen in the spectrum represents the signal that was applied to the ADC input while the low frequency noise represents 1/f noise. The sampling frequency of the system was 10 MHz while the frequency of the input tone is 6.25 KHz. The low frequency noise is clearly visible.

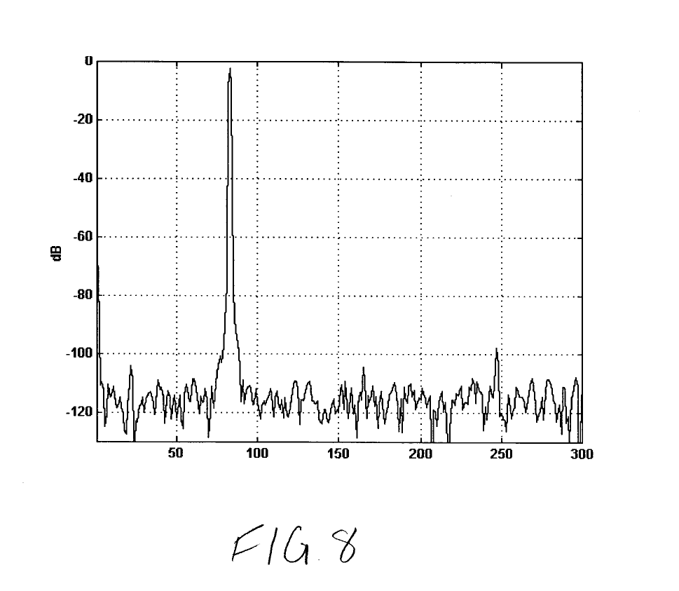

FIG. 8 shows the spectrum of the digitized output with chopping activated in accordance with the present invention. It was found that activation of the first block opamp chopping reduces the signal strength in the 0-76 Hz bands and 76-152 Hz bands by about 16 db and 18 dB, respectively. This represents a significant implement in overall converter signal-to-noise ratio (SNR) for low-frequency inputs. Table 1 below summarizes the effect of the opamp chopping on the converter performance.

TABLE 1
Comparison of converter performance and bin strengths with
and without opamp chopping.

| Opamp Chopping State | 1^{st} bin (0-76 Hz) | 2^{nd} bin (76-152 Hz) |
|---|---|---|
| Disabled | −49.8 dB | −55.8 dB |
| Enabled | −66 dB | −72.5 dB |

One skilled in the art will appreciate further features and advantages of the invention based on the above-described embodiments. Accordingly, the invention is not to be limited by what has been particularly shown and described, except as indicated by the appended claims. All publications and references cited herein are expressly incorporated herein by reference in their entirety.

What is claimed is:

1. A circuit, comprising:
a differential amplifier circuit;
a differential capacitive element coupled across the amplifier circuit in an integrating feedback configuration; and
an offset cancellation mechanism including input cross-coupled switches coupled between the differential capacitive element and the amplifier circuit inputs and output cross-coupled switches coupled between the differential capacitive element and the amplifier circuit outputs for swapping the amplifier circuit inputs and outputs to cancel chopper offset.

2. The circuit according to claim 1, further including an input switch network coupled between differential input signal terminals and the amplifier positive and negative inputs external to the integrating feedback configuration for swapping the differential input signal terminal connections to the amplifier positive and negative inputs.

3. The circuit according to claim 3, further including an output switch network coupled between differential output signal terminals and the amplifier positive and negative outputs external to the integrating feedback configuration.

4. The circuit according to claim 1, wherein the circuit corresponds to one stage in a sigma-delta type Analog-to-Digital Converter (ADC).

5. The circuit according to claim 1, wherein the differential capacitive element includes a filter capacitor.

6. The circuit according to claim 1, wherein the amplifier circuit includes a differential operational amplifier.

7. A circuit comprising:
a differential amplifier circuit having positive and negative inputs and positive and negative outputs;
a capacitive element across the differential inputs and outputs in an integrating configuration, the capacitive element including positive and negative differential components, each having a first end and a second end; and
a chopper mechanism for providing offset cancellation for the circuit, the chopper mechanism including
a first pair of cross-coupled switches including a first switch coupled between the first end of the capacitive element positive component and the negative input of the amplifier circuit and a second switch coupled between the first end of the capacitive element positive component and the positive input of the amplifier circuit;
a second pair of cross-coupled switches including a third switch coupled between the second end of the capacitive element positive component and the positive output of the amplifier circuit and a fourth switch coupled between the second end of the capacitive element positive component and the negative output of the amplifier circuit,
a third pair of cross-coupled switches including a fifth switch coupled between the first end of the capacitive element negative component and the negative input of the amplifier circuit and a sixth switch coupled between the first end of the capacitive element negative component and the positive input of the amplifier circuit; and
a fourth pair of cross-coupled switches including a seventh switch coupled between the second end of the capacitive element negative component and the positive output of the amplifier circuit and an eighth switch coupled between the second end of the capacitive element negative component and the negative output of the amplifier circuit such that the cross-coupled switches enable swapping of the inputs and outputs of the amplifier circuit for canceling chopper offset.

8. The circuit according to claim 7, further including an input switch network coupled between the amplifier inputs and differential signal input terminals for swapping a connection of the differential signal input terminals between the positive and negative input terminals of the amplifier circuit.

9. The circuit according to claim 7, further including an output switch network coupled to the amplifier output for swapping the positive and negative outputs of the amplifier circuit.

10. The circuit according to claim 7, wherein the capacitive element includes a filter capacitor.

11. The circuit according to claim 7, wherein the amplifier circuit includes a differential operational amplifier.

12. The circuit according to claim 7, wherein the circuit corresponds to one stage of a delta-signal Analog-to-Digital Converter (ADC).

13. An Analog-to-Digital Converter (ADC) circuit, comprising:
a differential amplifier circuit;
a differential capacitive element coupled across the amplifier circuit in an integrating feedback configuration; and
an offset cancellation mechanism including input cross-coupled switches coupled between the differential capacitive element and the amplifier circuit inputs and output cross-coupled switches coupled between the differential capacitive element and the amplifier circuit outputs for swapping the amplifier circuit inputs and outputs to cancel chopper offset.

14. The ADC circuit according to claim 13, wherein the ADC circuit is provided as a delta-sigma type ADC.

15. The ADC circuit according to claim 13, further including a quantizer coupled to the amplifier circuit.

16. A method for canceling chopper offset, comprising:
receiving a differential input signal;
storing a signal level of the input signal;
presenting a charge packet corresponding to the stored signal level to a differential amplifying circuit including an integrator feedback circuit; and
chopping the charge packet between positive and negative inputs of the differential amplifying circuit such that chopper offset is canceled.

17. The method according to claim 16, further including alternating differential input signal connections between the differential amplifier inputs external to the integrator feedback circuit.

18. The method according to claim 17, further including alternating differential output signals between the differential amplifier outputs external to the integrator feedback circuit.

19. The method according to claim 16, further including converting an analog signal to a digital signal.

20. The method according to claim 19, further including converting the analog signal in an delta-sigma type conversion.
